(19) United States
(12) Patent Application Publication
(10) Pub. No.: US 2013/0280519 A1
(43) Pub. Date: Oct. 24, 2013

(54) FLEXIBLE CERAMIC SUBSTRATE

(71) Applicant: SHAMROCK OPTRONICS CO., LTD., New Taipei City (TW)

(72) Inventors: CHUN-CHING HSIAO, New Taipei City (TW); CHIANG-CHUNG CHANG, New Taipei City (TW)

(73) Assignee: SHAMROCK OPTRONICS CO., LTD., New Taipei City (TW)

(21) Appl. No.: 13/733,128

(22) Filed: Jan. 2, 2013

(30) Foreign Application Priority Data
Apr. 20, 2012 (TW) 101114044

(51) Int. Cl. H05K 1/03

(52) U.S. Cl. CPC H05K 1/0306
USPC 428/325

(57) ABSTRACT

The present invention relates to a flexible ceramic substrate, which is a flexible substrate made of ceramic powder compound. The substrate includes a copper foil substrate having a thickness within a given range to form circuit board wiring through etching. The metal substrate has a surface on which a ceramic compound layer that is formed of a ceramic powder and a gum-like material of a predetermined weight ratio. The gum-like material fills in and wraps crystal gaps of the ceramic powder compound to bond the ceramic powder together to form a flexible ceramic compound layer of a predetermined thickness. The ceramic powder is bonded to the metal substrate to support heat-generating components and conduct and dissipate heat emitting from the heat-generating components.

### (a) TECHNICAL FIELD OF THE INVENTION

The present invention generally relates to a flexible ceramic substrate, and more particularly to a flexible ceramic substrate that is formed of ceramic powders enclosed by a gum-like material having a specific thickness.

### (b) DESCRIPTION OF THE PRIOR ART

The progress of time makes electronic products smaller and lighter and showing diversified shapes and working electronic components contained in the electronic devices are improved with respect to the performance thereof, making them giving off more and more heat generated by working, so that circuit substrates of electronic products are made to meet internal space of electronic products and also to handle heat dissipation of heat-generating electronic components. One of the most commonly used substrates in the industry is an aluminum substrate, which is comprised of a layer of copper foil, a layer of polyimide (PI) (or thermally conductive resin), and an aluminum board. However, PI or thermally conductive resin does not provide good heat dissipation performance so that the heat dissipation of the aluminum substrate is poor. Further, the aluminum substrate is of low shapeability, making it not applicable to products with curved surfaces. Thus, the conventional aluminum substrate does not meet the need of diversified internal space of electronic products for being not flexible. Another commonly used substrate in the industry is a flexible printed circuit board (FPCB), which suffers a severe challenge of insufficient heat dissipation. Due to the needs of being smaller and more diversified for electronic products and also due to the increase of operation temperature of electronic products caused by higher heat intensity, the lifespan and reliability of components and substrates are made worsened and the features of products deteriorated, affecting the progress of development of electronic products toward even thinner, lighter, and smaller, making it lag behind the trend of the time.

In view of the shortcomings of the conventional aluminum substrate and flexible printed circuit board that either are not flexible to comply with the diversified and narrow internal space of electronic products or are of insufficient heat dissipation, the present invention aims to provides a flexible substrate formed of ceramic powder compound that overcome both the poor flexibility issue of aluminum substrate and the poor heat dissipation of flexible printed circuit board.

### SUMMARY OF THE INVENTION

The primary object of the present invention is to provide a flexible ceramic substrate, in which a gum-like material is used to enclose ceramic powders to form a flexible ceramic substrate of a predetermined thickness in order to overcome the drawback of a conventional rigid aluminum substrate that cannot be deflected to comply with a product configuration and to provide heat dissipation performance exceeding that of the rigid aluminum substrate and to substantially improve the shortcoming of a conventional flexible printed circuit board that is of poor heat dissipation.

To achieve the above object, the present invention provides a flexible ceramic substrate, which comprises:

a metal base plate, which comprises a copper foil substrate of a predetermined thickness for forming a circuit board wiring through etching; and

a ceramic compound layer, which is formed by mixing a ceramic powder having a weight ratio and particle sizes that are with predetermined ranges and a gum-like material having a predetermined weight ratio,

wherein the gum-like material fills in and wraps crystal gaps of the ceramic powder to bond the ceramic powder together to form a flexible ceramic compound layer of a predetermined thickness, the ceramic compound layer being bonded to the metal base plate to support heat-generating components and also to conduct and dissipate the thermal energy emitting from the heat-generating components so a to overcome the drawback of the conventional aluminum substrate that is incapable of deflecting to comply with the configuration of a product and also to achieve heat dissipation performance that exceeds that of the rigid aluminum substrate.

A preferred embodiment of the present invention is to provide a flexible ceramic substrate, in which a ceramic compound layer has a surface that is not bonded to a metal base plate and is coated with a back adhesive that has an effect of heat dissipation so that the flexible ceramic substrate according to the present invention can be arbitrarily attached to and/or removed from an object.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a cross-sectional view showing a flexible ceramic substrate according to a preferred embodiment of the present invention.

FIG. 2 is a cross-sectional view showing a flexible ceramic substrate according to another embodiment of the present invention.

FIG. 3 shows curved that are obtained through measurements.

FIGS. 4-6 are schematic views illustrating the influence of ceramic powder contained in ceramic compound layer according to the present invention on particle size.

FIG. 7 is a curve of thickness vs. insulation strength for the flexible ceramic substrate according to the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims

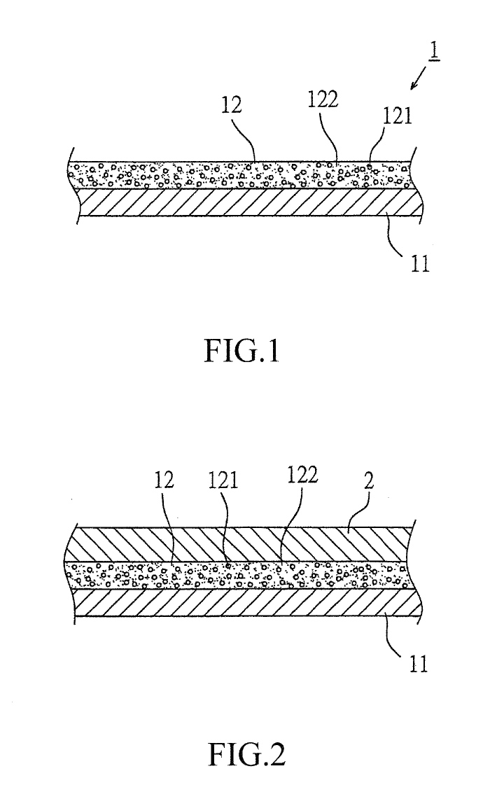

Referring first to FIG. 1, FIG. 1 is a cross-sectional view showing a flexible ceramic substrate according to a preferred embodiment of the present invention. The flexible ceramic substrate according to the present invention, generally designated at 1, comprises a base plate of metal 11 and a layer of ceramic compound 12. The metal base plate 11 comprises a copper substrate having a predetermined thickness. The copper substrate is provided for forming circuit board wiring through etching. The ceramic compound layer 12 is formed by mixing a ceramic powder 121 having a weight of a ratio between 22%-95% and particle size between 0.5 μm-30 μm and a gum-like material 122 having a weight of a ratio between 5%-78%. In an embodiment, the ceramic powder 121 is a power of excellent insulation property, such as aluminum nitride (AlN) powder, silicon carbide (SiC) powder, zinc oxide (ZnO) powder, and aluminum oxide (Al₂O₃), and the gum-like material 122 is PU acrylic glue, silicon rubber, rubber gum, or a mixture thereof. The ceramic compound layer 12 is formed by using the gum-like material 122 to enclose or wrap or fill in crystal gaps of the composition of ceramic powder 121 so as to bond the ceramic powder 121 together to form a flexible ceramic compound layer having a thickness exceeding 0.2 mm. The ceramic compound layer 12 can be bonded to the copper substrate of the body 1 by means of the adhesion of the gum-like material 122. The ceramic compound layer 12 has an example composition as listed in the following table:

| | | Ratio | | |
|---|---|---|---|---|
| | | Weight | | Weight |
| | | Ratio of | Particle | Ratio of |
| Powder Type | | Powder | Size | Gum |
| Ceramic | Aluminum Nitride | 22%-95% | 0.5 μm-30 μm | 78%-5% |
| Powder | Silicon Carbide | 26%-95% | 0.5 μm-30 μm | 74%-5% |
| | Zinc Oxide | 50%-95% | 0.5 μm-30 μm | 50%-5% |
| | Aluminum Oxide | 59%-95% | 0.5 μm-30 μm | 41%-5% |

Referring to FIG. 2, FIG. 2 shows a cross-sectional view of flexible ceramic substrate according to another embodiment of the present invention, in which a layer of back adhesive 2 that features heat dissipation is coated on the surface of the ceramic compound layer 12 that is not bonded to the copper substrate. In an embodiment, the back adhesive layer 2 may be formed of silicon rubber. The back adhesive layer 2 allows the flexible ceramic substrate 1 of the present invention to be arbitrarily attached to or removed from an object having a curved surface or an irregular surface.

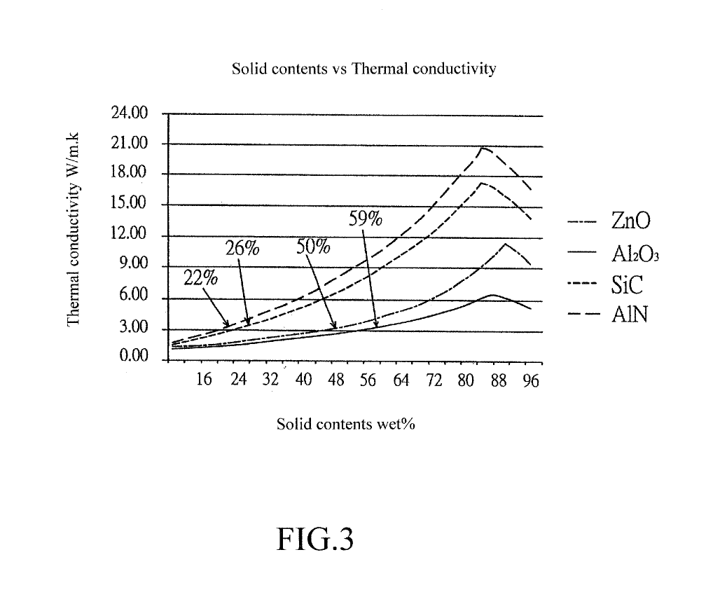

Referring to FIG. 3, FIG. 3 shows curves of solid contents and thermal conductivity according to measured results. The thermal conductivity of the conventional aluminum substrate is approximately 3 W/m·K and consequently, a circuit substrate material that meets the standard of the industry must be of a value at least 3 W/mK to be of market value. FIG. 3 shows curved that are obtained through practical measurement. These curves show that in the present invention, if the solid contents of silicon carbide (SiC) is greater than 26 w %, the solid content of aluminum nitride (AlN) greater than 22 w %, the solid content of zinc oxide (ZnO) greater than 50 w %, and the solid content of aluminum oxide (Al2O3) greater than 59 w %, the thermal conductivity can exceed the standard of 3 W/m·K. The curves of FIG. 3 also indicate that with the increase of solid content, the relative defects and strengths get more, leading to lowering of thermal conduction performance and when it exceed 95 w %, the performance of heat dissipation gets fast lowered and manufacture becomes difficult and yield rate get poor.

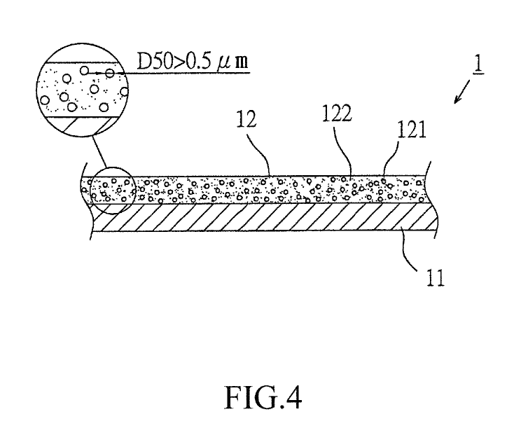

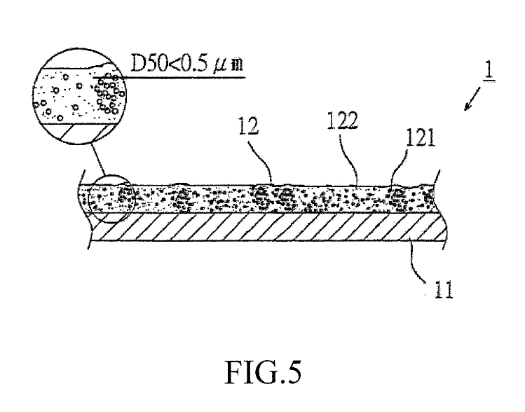

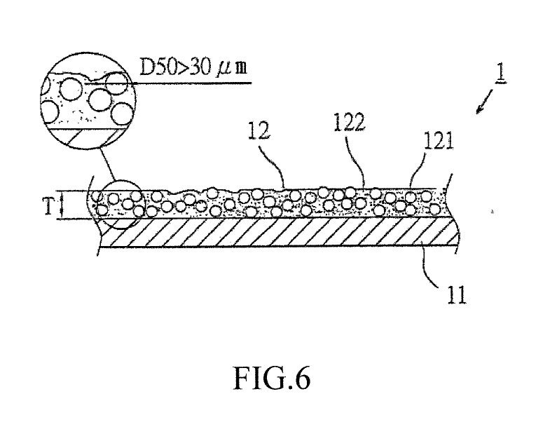

Referring to FIGS. 4 and 5, which are schematic views illustrating the influence of the ceramic powder contained in the ceramic compound layer on particle size, the particle size of the ceramic powder of the present invention has a minimum size that must exceed 0.5 μM in order to form an integral ceramic compound layer. When the minimum particle size of the ceramic powder is less than 0.5 μm, distribution may become inhomogeneous, leading to formation of void and even irregularity of surface. FIG. 6 shows that when the maximum particle size of the ceramic powder exceeds 30 μm, peeling may occur when the substrate so made has a thickness T=0.1 mm. Thus, the particle size of the ceramic powder used in the present invention is preferably between 0.5 μm-30 μm.

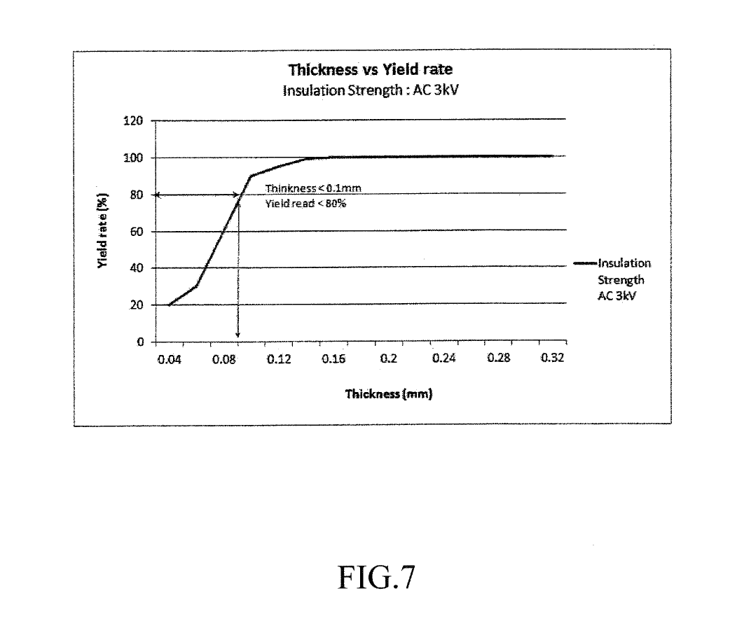

Referring to FIG. 7, a curve of thickness vs. insulation strength for the flexible ceramic substrate according to the present invention is shown. Since the substrate is generally provided to carry a circuit, insulation is a vital property. FIG. 7 shows that when the flexible ceramic substrate according to the present invention is made having a thickness of 0.06 mm, defects may occur and instability of insulation property may result. However, when the product of the present invention is made to have a thickness exceeding 0.08 mm, excellent insulation performance may be achieved.

Further, the ceramic compound layer can alternatively be a ceramic powder that is formed by mixing aluminum nitride powder, aluminum oxide powder, silicon carbide powder, and zinc oxide powder and have a weight ratio of 22%-95% and particle size of 0.5 μm-30 μm and a gum-like material that has a weight ratio of 78%-5%. Further, a surface of the copper foil substrate is coated with a solder mask layer for insulation purposes. The solder mask layer is formed of resin and white ceramic powder for light reflection. The white ceramic powder can be powder of aluminum oxide (Al₂O₃), titanium oxide (TiO₂), zinc oxide (ZnO), mica, zirconium silicate (ZrSiO₄). Alternatively, the solder mask layer can be replaced by a layer of white PI (Polyimide) film to reflect color lights. The surface of the ceramic compound layer that is not bonded to the metal base plate can be coated with a back adhesive and the back adhesive can silicon rubber or acrylic glue.

The effectiveness of the present invention is that a ceramic powder 121 that has insulation property and has a weigh ratio of 22%-95% and particle size of 0.5 μm-30 μm and a gum-like material 122 that has a weight ratio of 5%-78% are mixed together to form a ceramic compound layer 12. The ceramic compound layer 12 is adhesively bonded to a metal base plate 11 by the gum-like material 122 so that the flexible substrate 1 may deflect to comply with product configuration and also improve the heat dissipation performance of the circuit board.

In summary, the present invention provides a flexible ceramic substrate, which effectively overcomes the drawbacks of the conventional aluminum substrate and flexible printed circuit board of being either incapable of deflecting to comply with the diversified and narrow internal space of electronic products or being of insufficient heat dissipation and thus, the flexible ceramic substrate of the present invention is of high industrial value.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A flexible ceramic substrate, comprising:
a metal base plate, which comprises a copper foil substrate having a predetermined thickness; and
a ceramic compound layer, which is formed by mixing a ceramic powder having a weight ratio of 22%-95% and particle size of 0.5 μm-30 μm and a gum-like material having a weight ratio of 78%-5%;
wherein the gum-like material fills in and wraps crystal gaps of the ceramic compound layer to bond the ceramic powder together, the ceramic compound layer being bonded to the metal base plate and having a thickness greater than 0.8 mm.

2. The flexible ceramic substrate according to claim 1, wherein the ceramic powder comprises aluminum nitride powder.

3. The flexible ceramic substrate according to claim 1, wherein the ceramic powder comprises silicon carbide powder.

4. The flexible ceramic substrate according to claim 1, wherein the ceramic powder comprises zinc oxide powder.

5. The flexible ceramic substrate according to claim 1, wherein the ceramic powder comprises aluminum oxide powder.

6. The flexible ceramic substrate according to claim 1, wherein the gum-like material comprises PU acrylic glue, silicon rubber, rubber gum, or a mixture thereof.

7. The flexible ceramic substrate according to claim 1, wherein the ceramic powder is formed by mixing aluminum oxide powder, silicon carbide powder, and zinc oxide powder.

8. The flexible ceramic substrate according to claim 1, wherein the copper foil substrate has a surface coated with a solder mask layer for insulation and light reflection.

9. The flexible ceramic substrate according to claim 7, wherein the copper foil substrate has a surface coated with a solder mask layer for insulation and light reflection.

10. The flexible ceramic substrate according to claim 9, wherein the solder mask layer is formed of resin and white ceramic powder.

11. The flexible ceramic substrate according to claim 10, wherein the white ceramic powder selectively comprises powder of aluminum oxide (Al₂O₃), titanium oxide (TiO₂), zinc oxide (ZnO), mica, and zirconium silicate (ZrSiO₄).

12. The flexible ceramic substrate according to claim 8, wherein the solder mask layer comprises white polyimide.

13. The flexible ceramic substrate according to claim 9, wherein the solder mask layer comprises white polyimide.

14. The flexible ceramic substrate according to claim 1, wherein the ceramic compound layer has a surface that is not bonded to the metal base plat and is coated with back adhesive.

15. The flexible ceramic substrate according to claim 14, wherein the back adhesive comprises silicon rubber.
